(19) United States
(12) Patent Application Publication
(10) Pub. No.: US 2024/0237361 A1
(43) Pub. Date: Jul. 11, 2024

(54) 3D MEMORY DEVICE WITH A DRAM CHIP

(71) Applicant: Yangtze Memory Technologies Co., Ltd., Wuhan (CN)

(72) Inventors: Chao SUN, Wuhan (CN); Ning JIANG, Wuhan (CN)

(21) Appl. No.: 18/115,807

(22) Filed: Mar. 1, 2023

(30) Foreign Application Priority Data
Jan. 10, 2023 (CN) 202310036774.9

(51) Int. Cl. H10B 80/00

(52) U.S. Cl. CPC H10B 80/00

(57) ABSTRACT

A 3D memory device includes a first die of a 3D memory structure and a second die bonded with the first die. The second die includes DRAM cells. The 3D memory structure includes memory cells in a conductor/insulator stack. The conductor/insulator stack has conductive layers and dielectric layers alternatingly stacked over each other.

### CROSS-REFERENCE TO RELATED APPLICATION

This application claims the priority of Chinese Patent Application No. 202310036774.9, filed on Jan. 10, 2023, the content of which is incorporated herein by reference in its entirety.

### FIELD OF THE TECHNOLOGY

This application relates to the field of semiconductor technology and, specifically, to a three-dimensional (3D) memory device with a dynamic random-access memory (DRAM) chip and a fabrication method thereof.

### BACKGROUND OF THE DISCLOSURE

Not-AND (NAND) memory is a non-volatile type of memory that does not require power to retain stored data. The growing demands of consumer electronics, cloud computing, and big data bring about a constant need of NAND memories of larger capacity and better performance. As conventional two-dimensional (2D) NAND memory approaches its physical limits, 3D NAND memory is now playing an important role. 3D NAND memory uses multiple stack layers on a single die to achieve higher density, higher capacity, faster performance, lower power consumption, and better cost efficiency.

NAND memory is used extensively in solid-state drives (SSDs). NAND memory-based SSDs, for example, can provide much higher I/O performance than conventional hard-disk drives (HDDs). When a host (i.e., a host device) needs data from an NAND memory, it provides a logical address of the data to a memory controller. The memory controller identifies a physical address (e.g., a physical page address) of the data through a logical-to-physical mapping table, and then retrieves the data. The logical-to-physical address translation is crucial for the performance of NAND memory-based SSDs. As the logical-to-physical mapping table is kept in a mapping cache, high-capacity NAND memory-based SSDs require a high-capacity mapping cache, e.g., in the order of 1-2 MB per GB of an SSD. While a DRAM device can be made on an NAND memory chip for caching, it becomes challenging when a mapping cache with a large size (e.g., 8 GB) is required to boost the address translation. Alternatively, a discrete DRAM chip can be added in an SSD package to support a mapping cache. Such a method, however, incurs extra cost and power consumption.

### SUMMARY

In one aspect of the present disclosure, a 3D memory device includes a first die of a 3D memory structure and a second die bonded with the first die. The second die includes DRAM cells. The 3D memory structure includes a conductor/insulator stack and a region of memory cells in the conductor/insulator stack. The conductor/insulator stack includes conductive layers and dielectric layers alternatingly stacked over each other.

In another aspect of the present disclosure, a memory device includes a first die of a memory structure containing memory cells, a second die containing DRAM cells, and a third die of a periphery structure containing a periphery circuit. The first, second, and third dies are stacked.

In another aspect of the present disclosure, a method for fabricating a 3D memory device includes providing a first die of a 3D memory structure, providing a second die, and bonding the first die with the second die. The second die includes DRAM cells. The 3D memory structure contains a conductor/insulator stack and a region of memory cells in the conductor/insulator stack. The conductor/insulator stack includes conductive layers and dielectric layers that are alternatingly stacked.

Other aspects of the present disclosure can be understood by those skilled in the art in light of the description, the claims, and the drawings of the present disclosure.

### BRIEF DESCRIPTION OF THE DRAWINGS

FIG. 1 illustrates a top view of an exemplary structure at a certain stage during a fabrication process according to various aspects of the present disclosure;

FIGS. 2 and 3 illustrate cross-sectional views of the structure shown in FIG. 1 according to various aspects of the present disclosure;

FIGS. 4 and 5 illustrate a top view and a across-sectional view of the structure shown in FIGS. 1-3 after openings are formed according to various aspects of the present disclosure;

FIG. 6 illustrates a across-sectional view of the structure shown in FIG. 5 at a certain stage during the fabrication process according to various aspects of the present disclosure;

FIGS. 7 and 8 illustrate a top view and a across-sectional view of the structure at a certain stage according to various aspects of the present disclosure;

FIGS. 9 and 10 illustrate cross-sectional views of the structure shown in FIG. 8 at certain stages during the fabrication process according to various aspects of the present disclosure;

FIG. 11 illustrates a across-sectional view of the structure shown in FIG. 10 at a certain stage during the fabrication process according to various aspects of the present disclosure;

FIGS. 12 and 13 illustrate a cross-sectional view and a top view of the structure shown in FIG. 11 after certain openings are formed according to various aspects of the present disclosure;

FIGS. 14 and 15 illustrate cross-sectional views of the structure shown in FIGS. 12 and 13 at certain stages according to various aspects of the present disclosure;

FIGS. 16 and 17 illustrate cross-sectional views of the structure shown in FIG. 15 at certain stages according to various aspects of the present disclosure;

FIG. 18 illustrates a across-sectional view of the structure shown in FIG. 17 at a certain stage during the fabrication process according to various aspects of the present disclosure;

FIG. 19 illustrates a cross-sectional view of an exemplary periphery structure according to various aspects of the present disclosure;

FIG. 20 illustrates a cross-sectional view of an exemplary 3D memory array structure according to various aspects of the present disclosure;

FIG. 21 illustrates a cross-sectional view of a 3D memory device after the structure shown in FIG. 18, the periphery structure shown in FIG. 19, and the 3D memory array structure shown in FIG. 20 are bonded according to various aspects of the present disclosure;

FIG. 22 illustrates a cross-sectional view of the 3D memory device shown in FIG. 21 at a certain fabrication stage according to various aspects of the present disclosure;

FIG. 23 illustrates a schematic flow chart of fabrication of a memory device according to various aspects of the present disclosure;

FIG. 24 illustrates a block diagram of an exemplary system having memory devices according to various embodiments of the present disclosure;

FIG. 25 illustrates a diagram of an exemplary memory card having a memory device according to various aspects of the present disclosure; and

FIG. 26 illustrates a diagram of an SSD having memory devices according to various aspects of the present disclosure.

### DETAILED DESCRIPTION

The following describes the technical solutions according to various aspects of the present disclosure with reference to the accompanying drawings. Wherever possible, the same reference numbers will be used throughout the drawings to refer to the same or like parts. Apparently, the described aspects are merely some but not all of the aspects of the present disclosure. Features in various aspects may be exchanged and/or combined.

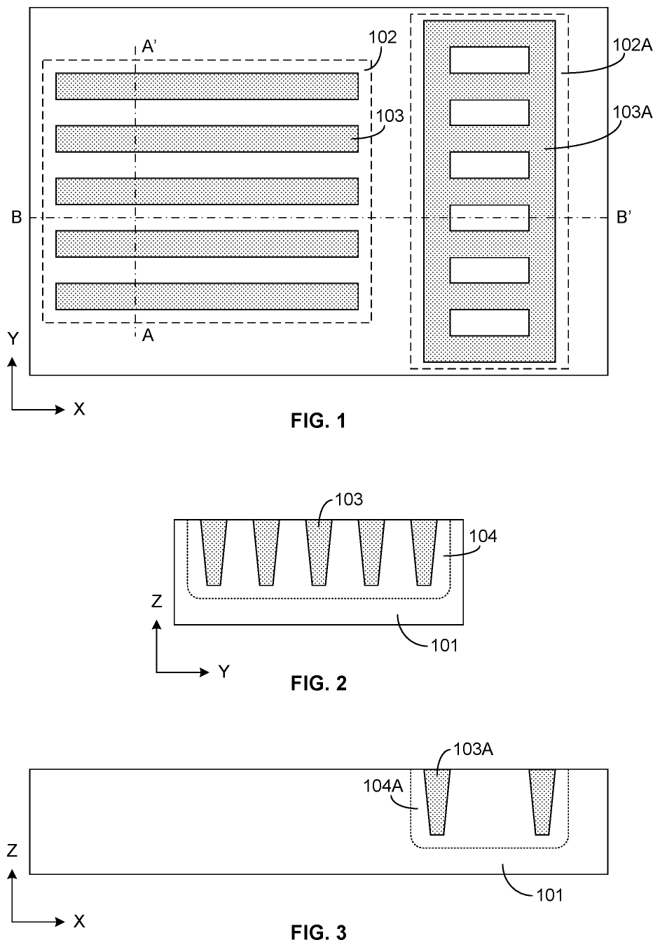

FIGS. 1-18 schematically show a fabrication process of an exemplary structure 100 according to aspects of the present disclosure. The structure 100 is a part of a memory device and includes a DRAM structure and certain circuits. The DRAM structure includes DRAM cells in DRAM regions. The structure 100 may also be referred to as a chip of DRAM structure or a die of a DRAM structure. Among the figures, top views are in an X-Y plane and cross-sectional views are in an X-Z or Y-Z plane.

FIG. 1 shows a schematic top view and FIGS. 2 and 3 show cross-sectional views of the structure 100 after isolation regions are formed according to aspects of the present disclosure. The cross-sectional views shown in FIGS. 2 and 3 are taken along lines AA′ and BB′ of FIG. 1, respectively. The structure 100 includes a substrate 101. In some aspects, the substrate 101 may include a single crystalline silicon layer. The substrate 101 may also include another semiconductor material, such as germanium (Ge), silicon-germanium (SiGe), silicon-on-insulator (SOI), or germanium-on-insulator (GOI). Optionally, the substrate 101 may have a thickness around 0.2 micrometers. As an example, the substrate 101 includes an undoped or lightly doped single crystalline silicon layer in descriptions below.

The structure 100 may include the DRAM structure with a DRAM region 102 and a complementary metal-oxide semiconductor (CMOS) region 102A exemplarily. The region 102 is arranged for DRAM cells, while the region 102A is arranged for CMOS circuits. Assuming the substrate 101 is lightly doped with n-type dopants. In some cases, p-well regions 104 and 104A are formed in the DRAM region 102 and CMOS region 102A, as shown in FIGS. 2 and 3. The p-well regions may be formed by ion implantation and/or diffusion. The dopants of the p-well regions may include, for example, boron (B) or gallium (Ga).

Further, openings (not shown) are formed by dry and/or wet etch in the DRAM region 102 and CMOS region 102A. The openings may have a taper angle, i.e., the horizontal dimension of the openings decreases gradually from the top to the bottom. A deposition process is performed subsequently to fill the openings by one or more dielectric materials (e.g., silicon oxide). Dielectric regions 103 and 103A are formed by the filling process. In an X-Y plane, the dielectric regions 103 may be parallel to the X axis with certain spacing and extend along the X direction. In the Z direction or vertical direction, the regions 103 extend to a depth, and the regions 103A extend to another depth. In some cases, the dielectric region 103A may be referred to as shallow trench isolation (STI). Chemical vapor deposition (CVD) and/or atomic layer deposition (ALD) may be used in the filling process.

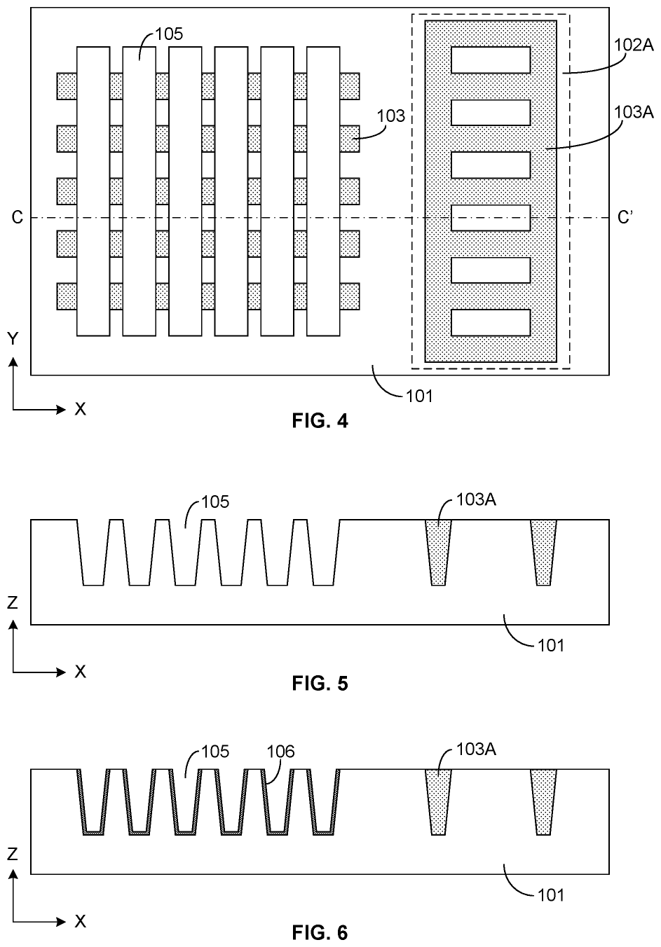

FIGS. 4 and 5 show a schematic top view and a schematic cross-sectional view of the structure 100 after openings 105 are formed according to aspects of the present disclosure. The cross-sectional view shown in FIG. 5 is taken along a line CC′ of FIG. 4. As shown in FIG. 5, the openings 105 may also have a taper angle. In an X-Y plane, the openings 105 may be parallel to the Y axis with certain spacing and extend along the Y direction. As such, the openings 105 and dielectric regions 103 are perpendicular to each other in a horizontal plane. In the Z direction, the openings 105 may extend to a depth that is smaller or shallower than that of the dielectric region 103. The quantity, dimension, shape, profile, and arrangement of the openings 105 and regions 103 and 103A as shown in FIGS. 4 and 5 and in other figures in the present disclosure are exemplary and for description purposes.

Further, a dielectric material is deposited to form a layer 106 on the sidewalls and bottom surfaces of the openings 105 by CVD and/or ALD. The layer 106 is a gate dielectric layer for a metal-oxide-semiconductor field-effect transistor (MOSFET) of a DRAM cell. The layers 106 are shown schematically in FIG. 6.

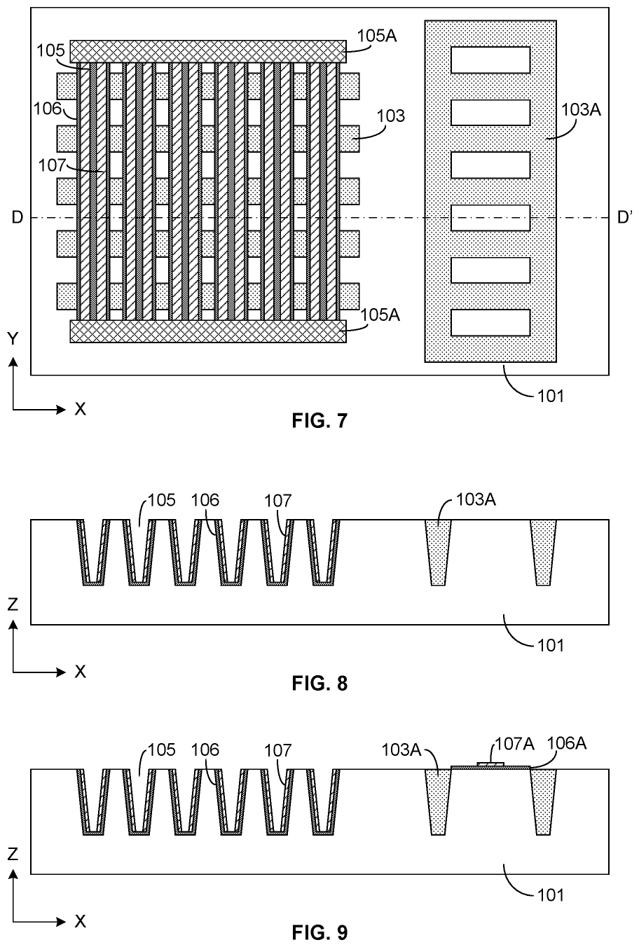

FIGS. 7 and 8 show a schematic top view and a schematic cross-sectional view of the structure 100 at a certain stage of the fabrication process according to aspects of the present disclosure. The cross-sectional view shown in FIG. 8 is taken along a line DD′ of FIG. 7. After the dielectric layer 106 is made, a conductive layer 107 is deposited over the layer 106. The layer 107 is a gate layer or vertical gate for the MOSFET and may contain a conductive material such as tungsten (W), copper (Cu), molybdenum (Mo), ruthenium (Ru), doped polysilicon, etc. The layer 107 on the bottom surface is removed by etch (e.g., a dry etch) subsequently. In some embodiments, openings (not shown) are made in the boundary areas of the DRAM region 102 by dry etch and/or wet etch and certain end sections of the openings 105 are removed. These openings are filled with a dielectric material such as silicon oxide to create dielectric regions 105A, as shown in FIG. 7. As such, the layers 107 on the opposite sidewalls of an opening 105 are electrically isolated. The layers 107 will be used as word lines for the DRAM structure. In some other cases, the dielectric regions 105A may be made at a later stage.

Further, certain fabrication processes may be performed to make CMOS circuits in the CMOS region 102A. For example, a gate dielectric layer 106A and a gate layer 107A may be deposited by CVD and/or ALD, as shown in FIG. 9. When the supply voltages of the DRAM cells in the DRAM region 102 and the CMOS circuits in the CMOS region 102A are similar or in a certain range, the gate dielectric layers 106 and 106A may be made using the same process or similar processes, and the gate layers 107 and 107A may also be made using the same process or similar processes. Further, in these cases, the gate dielectric layers 106 and 106A may contain the same material, and the gate layers 107 and 107A may also contain the same material. When the processes and materials to make the DRAM cells and CMOS circuits are the same or similar, the fabrication cost may be reduced.

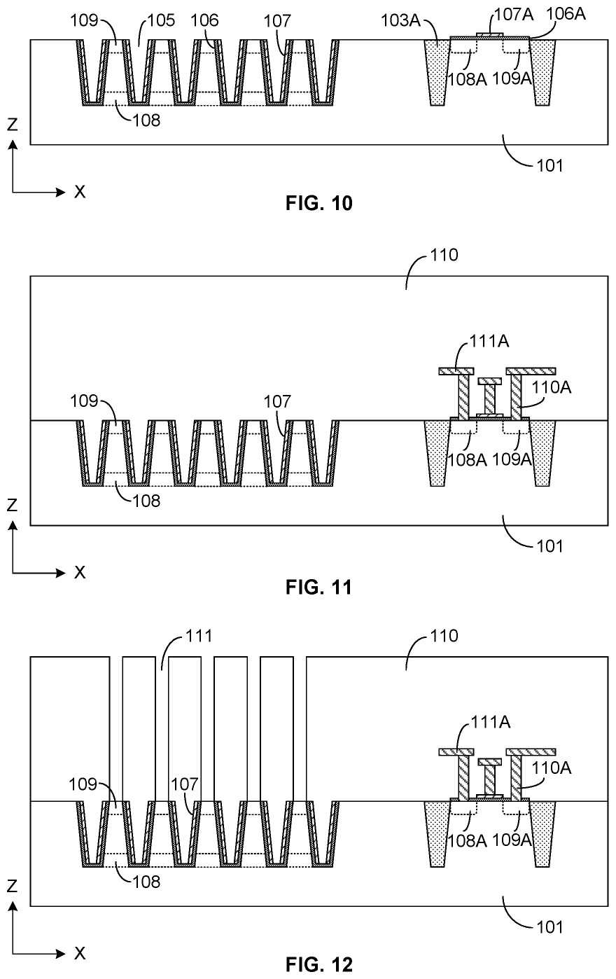

FIG. 10 shows a schematic cross-sectional view of the structure 100 after an ion implantation process according to aspects of the present disclosure. The ion implantation process is performed to create drain regions 108 and source regions 109 for the MOSFETs of the DRAM cells. Materials such as phosphorus (P), arsenic (As), and/or antimony (Sb) may be used as dopants in the implants. The drain region 108 and source region 109 are between adjacent openings 105 or between dielectric layers 106 on sidewalls of adjacent openings 105. The source region 109 is configured over the drain region 108 in the Z direction. The vertical gate 107, gate dielectric layer 106, drain region 108, and source region 109 are fabricated to construct the MOSFET of a DRAM cell.

Similarly, drain regions 108A and source regions 109A are form by ion implantation in the CMOS region 102A. Further, other CMOS fabrication processes are performed to make p-channel MOS (PMOS) and n-channel MOS (NMOS) for the CMOS circuits. When the supply voltages of the DRAM cells in the DRAM region 102 and the CMOS circuits in the CMOS region 102A are similar or in a certain range, the same process or similar process may be used to form the drain and source regions 108-109 and 108A-109A, respectively. In some embodiments, low-voltage (e.g., lower than 30 volts) CMOS is arranged in the CMOS region 102A. In some cases, for example, the CMOS supply voltage is lower than 2-5 volts. As the supply voltage of the DRAM cell is lower than 2 volts, fabrication of DRAM cells in the DRAM region 102 and CMOS circuits in the CMOS region 102A may share certain processes, providing a cost saving method in some embodiments.

Further, dielectric materials (e.g., silicon oxide) are deposited over the top surface by CVD. The openings 105 are filled and a dielectric layer 110 is formed over the DRAM region 102 and CMOS region 102A. Then, vias (or contacts) 110A and conductor layers (or metal lines) 111A are fabricated for the CMOS circuits. The CMOS circuits in the CMOS region 102A may be designed to support the operation of the DRAM cells and/or the memory device. The vias 110A and conductor layers 111A may contain conductive materials, e.g., W, Cu, cobalt (Co), aluminum (Al), titanium (Ti), or a combination thereof. Thereafter, dielectric material are deposited, covering the vias and conductor layers and thickening the dielectric layer 110, as shown in FIG. 11.

Various types of field-effect transistors (FETs) may be used to make CMOS circuits in the CMOS region 102A. For example, besides the bulk FET structure shown in FIG. 10, bulk FinFET may also be used to construct the CMOS circuits. In some cases, the substrate 101 is an SOI substrate and the CMOS circuits may include SOI CMOS or SOI FinFET.

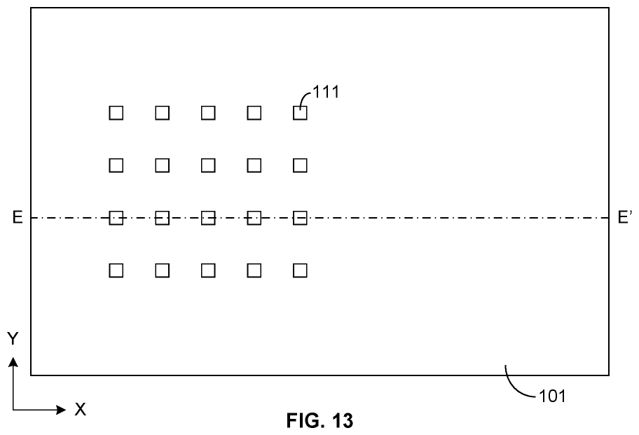

FIGS. 12 and 13 show a schematic cross-sectional view and a schematic top view of the structure 100 after openings 111 are made according to aspects of the present disclosure. Dry etch and/or wet etch may be employed to make the openings. The cross-sectional view shown in FIG. 12 is taken along a line EE′ of FIG. 13. The openings 111 are arranged for making storage capacitors of the DRAM cells. In an X-Y plane, the configuration of the openings 111 reflects an exemplary pattern of the DRAM cells. Along the Z direction or vertical direction, the openings 111 are aligned to the source regions 109 respectively, extend through the dielectric layer 110, and expose the source regions 109 at the bottom.

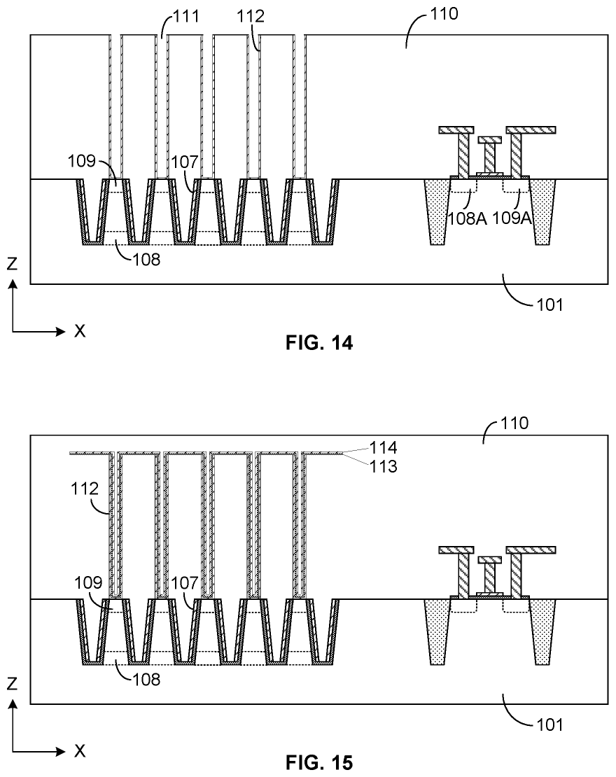

Further, a conductive layer 112 is deposited on the sidewalls and bottom surfaces of the openings 111 by CVD and/or ALD, as depicted in FIG. 14. The layer 112 in an opening 111, electrically contacting the source region 109, may be referred to as the bottom electrode of the capacitor of a DRAM cell. Thereafter, a dielectric layer 113 and a conductive layer 114 are deposited sequentially by CVD and/or ALD. The layers 113 and 114 are formed on the sidewalls and bottoms of the partially filled opening 111 and certain top areas of the dielectric layer 110. The layer 114 may be referred to as the top electrode of the capacitor. The layers 112 and 114, as the bottom and top electrodes grown on the sidewall of the opening 111, extend in the Z direction. In some embodiments, the layer 114 is connected to the ground. As such, the top electrodes at DRAM cells in a certain region may be connected to the ground. Optionally, the layer 113 may contain a high-k dielectric material (e.g., aluminum oxide or hafnium oxide), and the layers 112 and 114 may contain a conductive material such as W, Cu, Mo, Ru, or doped polysilicon. Thereafter, a dielectric material is deposited to fill the partially filled openings 111 and cover the layer 114, thickening the layer 110, which is shown in FIG. 15.

In some cases, the openings 111 may be referred to as trenches and the storage capacitors may be called trench capacitors. The openings 111 may have a taper angle, a cup shape, or a pillar shape in some aspects. As illustrated above, a DRAM cell may contain a single-gate MOSFET, where the layer 107 is the insulated vertical gate structure. Optionally, a DRAM cell may contain a MOSFET with double gates. Alternatively, a DRAM cell may contain a gate-all-around (GAA) FET with a vertical gate structure. In some other cases, the DRAM cell may contain a MOSFET with a horizontal gate structure or recessed gate structure.

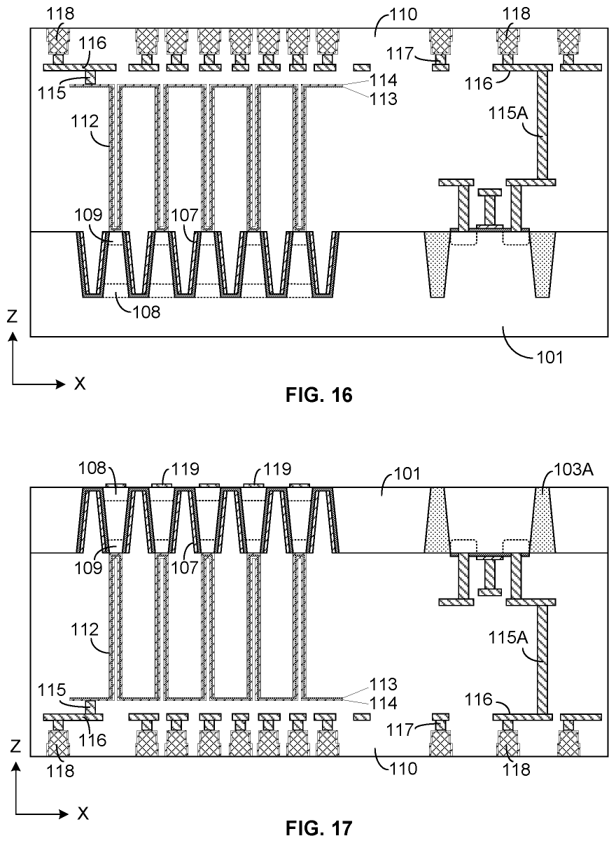

After the DRAM cells and CMOS circuits are made, dielectric materials such as silicon oxide are deposited by CVD and the dielectric layer 110 is thickened further. Vias 115 and 115A and conductor layers 116 are made for interconnect. For example, the vias 115 and 115A may be deposited by CVD to connect with certain contacts of the DRAM cells and CMOS circuits. Then, vias 117 and connecting pads 118 are formed in the dielectric layer 110, as shown in FIG. 16. The connecting pads 118 are formed to connect with a memory array structure or a periphery structure. The vias 115 and 117, conductor layers 116, and connecting pads 118 may include a conductive material such as W, Co, Cu, Al, Ti or a combination thereof.

Further, the structure 100 is placed upside down. Part of the substrate 101 is removed from the bottom by a thinning process, such as wafer grinding, dry etch, wet etch, chemical mechanical polishing (CMP), or a combination thereof. After the thinning process, the drain regions 108 and dielectric region 103A are exposed. As such, the dielectric region 103A penetrates through the substrate 101 completely along a direction approximately perpendicular to the substrate 101 or the Z direction. A conductive material is deposited by CVD and/or ALD, forming a conductive layer 119 over the exposed drain regions 108, as shown in FIG. 17. The conductive layer 119 electrically contacts the drain region 108 and may contain, for example, W, Cu, or doped polysilicon. In some embodiments, the conductive layer 119 may be connected to a bit line of the DRAM structure.

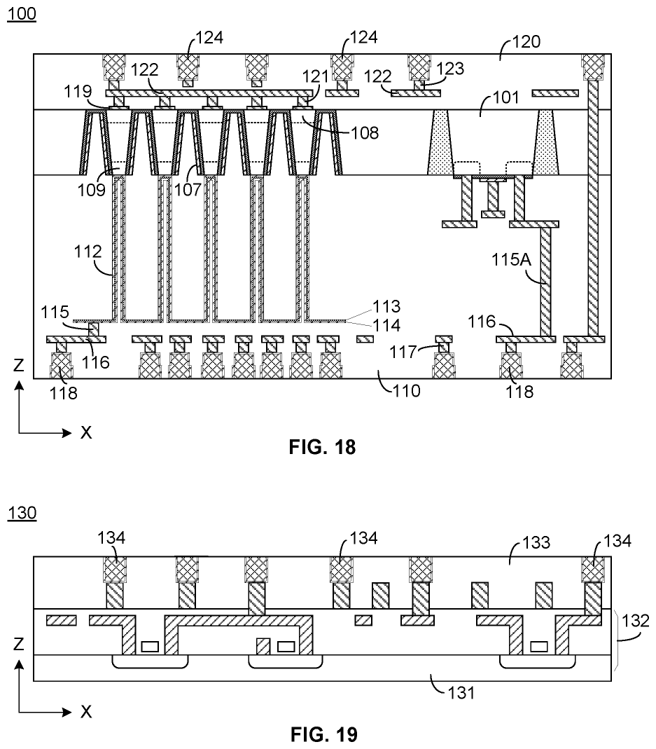

Thereafter, a dielectric material (e.g., silicon oxide) is deposited and a dielectric layer 120 is formed over the layer 119. Openings (not shown) are etched and subsequently filled with a conductive material to make vias 121 that connect to the layers 119 and certain contacts of the CMOS circuits. Then, conductor layers 122, vias 123, and connecting pads 124 are formed sequentially, as shown in FIG. 18. One of the conductor layers 122 is a bit line that connects to drain regions 108 of certain DRAM cells. The vias 121 and 123, conductor layers 122, and connecting pads 124 may contain the same material as or similar material to that of the vias, conductor layers, and connecting pads illustrated above. The structure shown in FIG. 18 may be referred to as the structure 100.

FIG. 19 shows a cross-sectional view of an exemplary periphery structure 130 according to aspects of the present disclosure. The periphery structure 130 is another part of the memory device and may also be referred to as a die (or chip) of a peripheral structure. The periphery structure 130 includes a substrate 131 that may include a semiconductor material such as single crystalline silicon, Ge, SiGe, SiC, SOI, or GOI. Periphery CMOS circuits 132 (e.g., control circuits) are fabricated on the substrate 131 and used for facilitating the operation of the memory device. For example, the periphery CMOS circuits 132 may provide functional devices such as page buffers, sense amplifiers, column decoders, and row decoders. A dielectric layer 133 is deposited over the substrate 131 and CMOS circuits 132. Connecting pads (such as connecting pads 134) and vias are formed in the dielectric layer 133. The dielectric layer 133 includes one or more dielectric materials such as silicon oxide and silicon nitride. The connecting pads 134 are arranged to connect with connecting pads of a memory array device or the structure 100 and include a conductive material such as W, Co, Cu, Al, Ti or a combination thereof.

In some embodiments, the periphery CMOS circuits 132 may include both low-voltage circuits and high-voltage circuits. For example, the supply voltage V1 of some circuits may be lower than 30 volts, while the supply voltage V2 of some other circuits may be close to or higher than 30 volts. In comparison, the supply voltage V0 of the CMOS circuits in the CMOS region 102A of the structure 100 may be much lower than 30 volts. As such, V2 is larger than V1, while V1 is larger than V0. For example, in some cases, V2 may be in a range of 20-35 volts, V1 may be around 3 volts, and V0 may be around 1 volt. Further, in some cases, only CMOS circuits with a certain supply voltage are configured in the CMOS region 102A. For example, only CMOS circuits with a supply voltage below 2-5 volts are configured in the CMOS region 102A. As a result, some fabrication processes may be similar or the same when the DRAM cells and CMOS circuits are made.

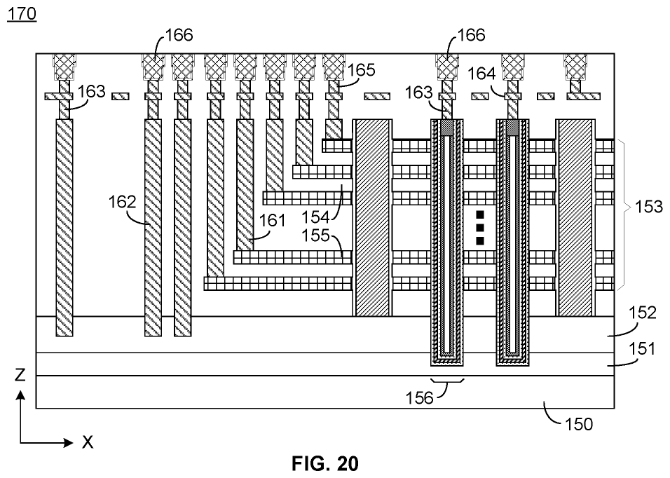

FIG. 20 shows a cross-sectional view of an exemplary 3D memory array structure 170 according to aspects of the present disclosure. The 3D memory array structure 170 may also be referred to as a die (or chip) of a 3D memory array structure. The memory array structure 170 is built over a substrate 150. The substrate 150 may include a semiconductor material such as single crystalline silicon. Layers 151 and 152 are deposited over the substrate 150. The layers 151 and 152 may be, e.g., silicon oxide and polysilicon, respectively. The layer 151 is a sacrificial layer. Over the layer 152, a conductor/insulator stack 153 is formed. The conductor/insulator stack 153 contains dielectric layers 154 and conductive layers 155 that are alternatingly stacked over each other. The dielectric layer 154 and conductive layer 155 may have a dielectric material (e.g., silicon oxide) and a conductive material (e.g., W), respectively.

Channel hole structures 156 are made through the conductor/insulator stack 153. The channel hole structure 156 is made in a channel hole, and includes a functional layer deposited on the sidewall of the channel hole and a semiconductor channel deposited on the functional layer. The functional layer may include a blocking layer, a charge trap layer, and a tunneling layer that are grown sequentially. The blocking layer, charge trap layer, and tunneling layer are dielectric layers, such as a silicon oxide layer, a silicon nitride layer, and another silicon oxide layer. The semiconductor channel may include a polysilicon layer. The conductive layer 155 is the word line of the 3D memory array structure 170. The semiconductor channel is the bit line. Contacts 161 are made to connect to the conductive layer 155. Contacts 162 are interconnect contacts. Vias 163 and 165, conductor layers 164, and connecting pads 166 are made over the conductor/insulator stack 153 and contacts 161-162.

For the structure 100, periphery structure 130, and 3D memory array structure 170, the bottom side of the substrate may be referred to as the back side, and the side opposite to the back side may be referred to as the front side or face side. For example, connecting pads 118, 134, and 166 are on the front side, while connecting pads 124 are on the back side.

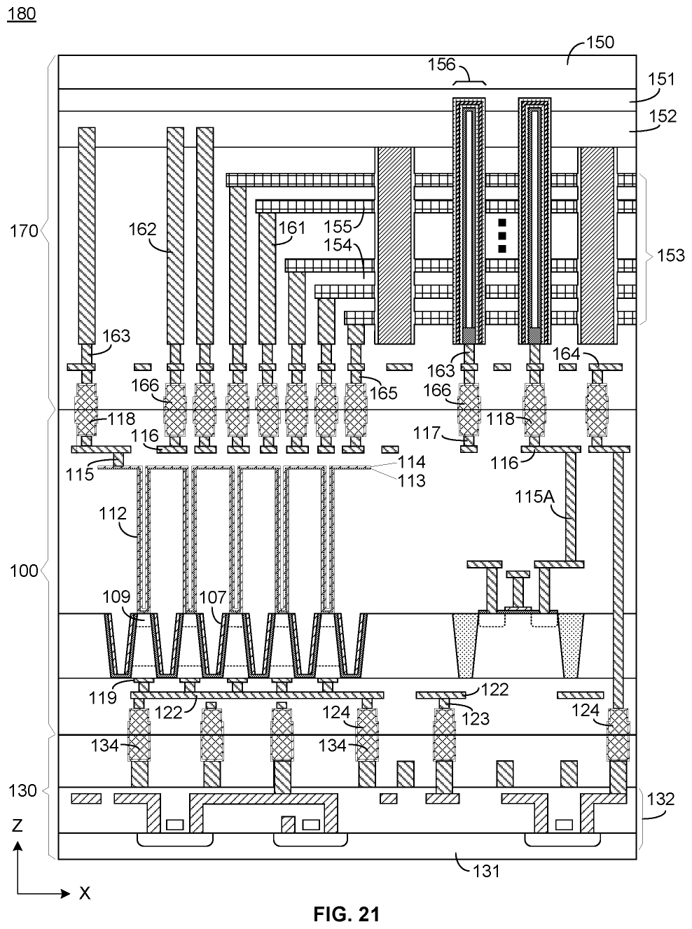

FIG. 21 schematically shows an exemplary 3D memory device 180 in a cross-sectional view according to aspects of the present disclosure. The 3D memory device 180 includes the structure 100 shown in FIG. 18, the periphery structure 130 shown in FIG. 19, and the 3D memory array structure 170 shown in FIG. 20. The three structures may be stacked over each other in the Z direction or vertical direction. In some embodiments, the structure 100, periphery structure 130, and 3D memory array structure 170 are fabricated separately and then bonded together to form the 3D memory device 180. Optionally, the structure 100 may be sandwiched between the periphery structure 130 and 3D memory array structure 170, as depicted in FIG. 21.

In an exemplary assembly process, the structure 100 is placed over the periphery structure 130, with connecting pads 124 and 134 aligned and then bonded. As such, the back side of the structure 100 is attached to the front side of the periphery structure 130. Thereafter, the 3D memory array structure 170 is fixed by a flip-chip bonding method. The 3D memory array structure 170 is flipped vertically and becomes upside down. After an alignment is made, e.g., the connecting pads 166 being aligned with the connecting pads 118, respectively, the 3D memory array structure 170 and structure 100 are joined face to face and bonded together. In some aspects, a solder or a conductive adhesive is used to bond the connecting pads and make bonded connecting pads electrically connected. Alternatively, the structure 100 may be bonded with the 3D memory array structure 170 to form a subassembly and then the subassembly is bonded with the periphery structure 130.

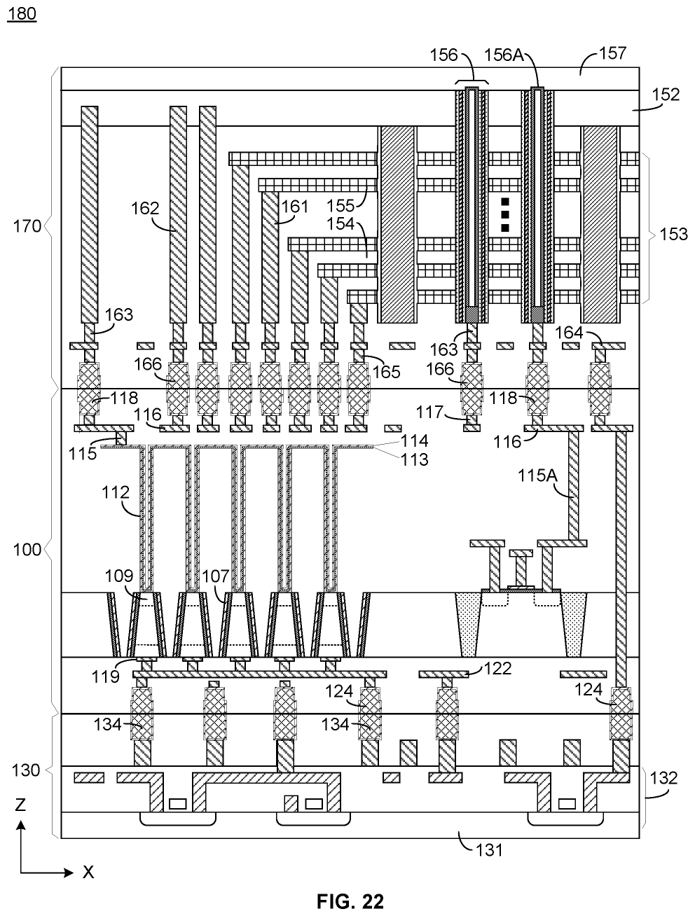

Further, in some embodiments, a thinning process (e.g., dry etch, wet etch, and/or CMP) is performed to remove the substrate 150 of the 3D memory array structure 170 from the back side. The layer 151 is exposed and subsequently etched away by a selective wet etch. Removal of the layer 151 exposes the functional layer of the channel hole structure 156. The functional layer, including the blocking layer, charge trap layer, and tunneling layer are etched selectively to expose the semiconductor channel, for example, a semiconductor channel 156A. A conductive material or semiconductor material (e.g., doped polysilicon) is deposited to form a conductive layer 157, as shown in FIG. 22. The conductive layer 157 electrically connects with the semiconductor channels of the channel hole structures 156 and may function as an array common source in some cases. Further, additional fabrication steps or processes are performed to complete fabrication of the 3D memory device 180. Details of the additional fabrication steps or processes are omitted for simplicity.

There are additional or alternative methods aside from what illustrated above. In some embodiments, the periphery structure 130 is made first, and the 3D memory array structure 170 is built using the periphery structure 130 as a substrate component, making an integrated structure. The structure 100 and the integrated structures are then bonded together to form the 3D memory device 180.

Alternatively, the structure 100 is made first, and the 3D memory array structure 170 is made using the structure 100 as a substrate component, making an integrated structure. The periphery structure 130 and the integrated structure are then bonded together to form the 3D memory device 180.

In some embodiments, the structure 100 contains DRAM cells and CMOS circuits of low supply voltage (e.g., only containing circuits with supply voltage lower than 30 volts), while the periphery structure 130 has CMOS circuits of high supply voltage (e.g., equal to or higher than 30 volts). The CMOS circuits and DRAM cells at the structure 100 may share certain fabrication processes.

In some embodiments, the structure 100 has DRAM cells and CMOS circuits of low supply voltage (e.g., only containing circuits with supply voltage lower than 2 volts), while the periphery structure 130 has CMOS circuits with low supply voltage and high supply voltage. The CMOS circuits and DRAM cells at the structure 100 may share certain fabrication processes.

In some other cases, the structure 100 contains DRAM cells and does not have CMOS circuits. In these cases, the periphery structure 130 has CMOS circuits ranging from the low-voltage to high-voltage type. The CMOS circuits as mentioned above, with low or high supply voltage, are arranged to facilitate the operation of the 3D memory device.

In some embodiments, the structure 100, periphery structure 130, and 3D memory array structure 170 are fabricated separately. The three structures are stacked over each other by bonding, and the 3D memory array structure 170 is disposed between the structure 100 and periphery structure 130.

Because the structure 100 is made using a separate substrate, it may have a high capacity. When the structure 100 is used as illustrated above, it provides a high-capacity mapping cache (e.g., 8 GB) to support the operation of high-capacity NAND memory-based SSDs. Compared to adding a DRAM device to an SSD package, the cost and power consumption may be reduced. Further, when certain low-voltage CMOS circuits are made at the structure 100, the circuits and DRAM cells may share some fabrication process, further reducing the manufacturing cost.

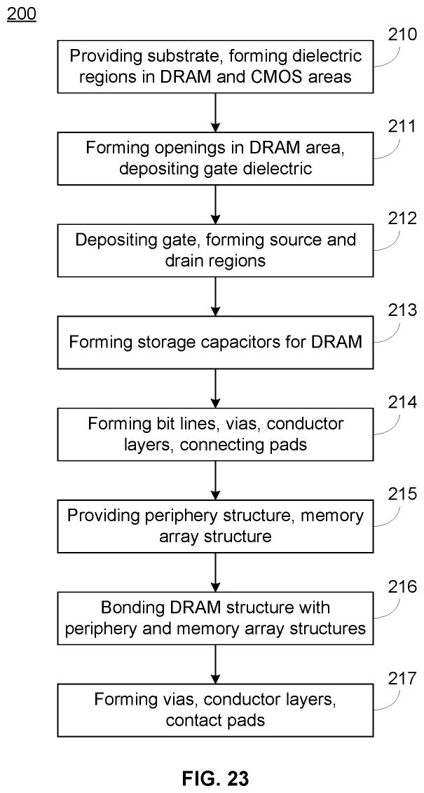

FIG. 23 shows a schematic flow chart 200 for fabricating a memory device according to aspects of the present disclosure. At 210, a substrate is provided for fabricating a DRAM and CMOS structure. The DRAM and CMOS structure contains a DRAM structure and certain CMOS circuits. The DRAM structure contains DRAM cells in a DRAM area. The substrate includes a semiconductor substrate, such as a single crystalline silicon substrate. The DRAM area and a CMOS area for CMOS circuits are defined on the substrate. In some cases, n-wells and/or p-wells are formed by, for example, ion implantation or diffusion. First openings including trenches are etched and then filled with a dielectric material (e.g., silicon oxide) to make dielectric regions in the DRAM and CMOS areas. The dielectric regions in the DRAM area may form rows. The rows are parallel with certain spacing to a first direction (e.g., X direction) and extend along the first direction. (e.g., X direction).

At 211, second openings such as trenches are formed in the DRAM area. The second openings may form columns that are parallel with certain spacing to a second direction (e.g., Y direction), and extend long the second direction. The second direction is perpendicular to the first direction. The second openings are perpendicular to the dielectric regions in the DRAM area, and cross the dielectric regions. A high-k dielectric material is deposited on the sidewalls of the second openings to form the gate dielectric for the DRAM cells. In the CMOS area, a high-k dielectric material is deposited to form the gate dielectric for the CMOS circuits.

At 212, a conductive material is deposited over the gate dielectric to form the gate for the DRAM cells. In the DRAM area, the gate electric and the gate are grown on the sidewall of the second opening, creating a vertical gate structure. In the CMOS area, a conductive material is also deposited, making the gate for the CMOS circuits. Further, ion implantation is performed to form source regions and drain regions in the DRAM area. In some aspects, the source region is arranged over the drain region in the vertical direction. Ion implantation is also conducted to create source regions and drain regions for the CMOS circuits in the CMOS area. As such, FETs are made for the DRAM cells and CMOS circuits. The FET of the DRAM cell may have a vertical gate, and the FET of the CMOS circuits may be SOI FinFET in some cases. The vertical gate is the word line of the DRAM structure.

Further, a dielectric material is deposited to form a dielectric layer over the DRAM and CMOS areas, covering the FET structures. Vias and conductor layers for made over the CMOS area to connect with the gate, source region, and drain region of the CMOS circuits.

At 213, third openings are etched in the dielectric layer for making storage capacitors. The third openings are aligned to and expose the source regions of the FETs of the DRAM cells, respectively. A conductive material is deposited on the sidewall and bottom of the third openings, forming a bottom electrode of the capacitor. The bottom electrode electrically contacts the source region. Thereafter, a high-k dielectric material is deposited on the bottom electrode, followed by deposition of a conductive material. A top electrode of the capacitor is formed. The capacitors have electrodes that extend vertically. A dielectric material is deposited to cover the capacitors, thickening the dielectric layer.

At 214, vias, conductor layers, and connecting pads are made for the DRAM cells in the DRAM area and the CMOS circuits in the CMOS area on the front side of the DRAM and CMOS structure. Further, the DRAM and CMOS structure is turned upside down. A thinning process is performed to remove a part of the substrate of the DRAM and CMOS structure. The drain regions of the DRAM cells are exposed. Conductive layers are deposited over the drain regions. The drain region is connected to a bit line of the DRAM structure through the conductive layer. A dielectric layer is deposited to cover the conductive layers, followed by etching openings in the dielectric layer. The openings are then filled with a conductive material to form vias. Further, conductor layers, additional vias, and connecting pads are made on the back side of the DRAM and CMOS structure.

At 215, a periphery structure and a memory array structure are provided. In some cases, the CMOS circuits at the DRAM and CMOS structure are low-voltage circuits, while the CMOS circuits at the periphery structure are high-voltage circuits. Optionally, the CMOS circuits at the periphery structure may contain both low-voltage and high-voltage circuits. In some cases, the DRAM cells and the CMOS circuits at a DRAM and CMOS structure have the same supply voltage or similar supply voltages and may share some fabrication process.

The memory array structure may include memory cells configured in a 2D array or 3D array. A 3D memory array structure may include a conductor/insulator stack that has conductive layers and dielectric layers alternatingly stacked over each other. Memory cells are made through the conductor/insulator stack.

At 216, the DRAM and CMOS structure, periphery structure, and memory array structure are stacked over each other by bonding. In some cases, the back side of the DRAM and CMOS structure is attached to and bonded with the front side of the periphery structure, and the front side of the DRAM and CMOS structure is attached to and bonded with the front side of the memory array structure. The back side of the memory array structure becomes facing upward.

At 217, the substrate of the memory array structure is thinned or removed. Deposition processes are performed to form vias, conductor layers, and contact pads. The contact pads are configured for wire bonding for connection between the memory device and other devices.

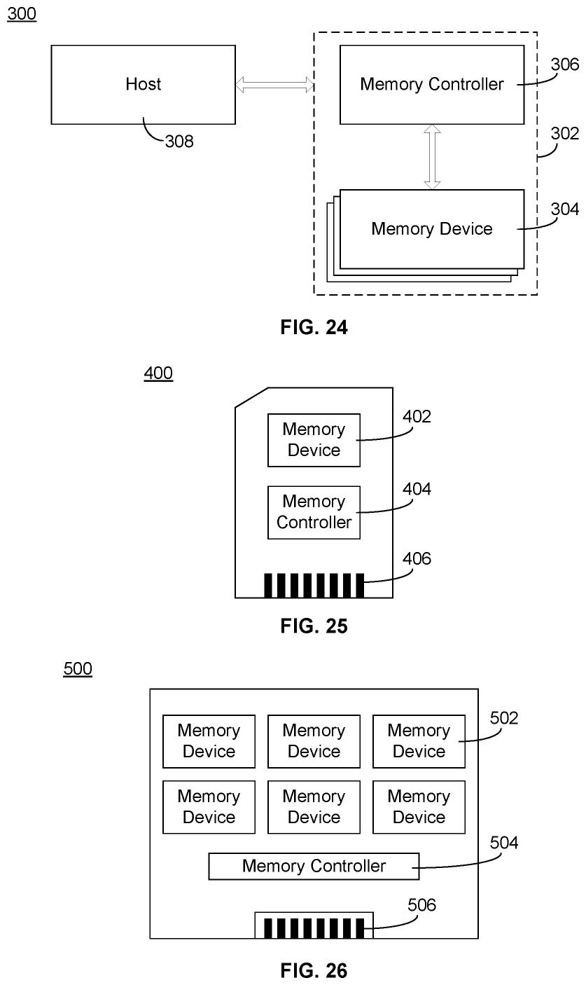

FIG. 24 shows a block diagram of an exemplary system 300 having a memory device according to various aspects of the present disclosure. The system 300 may be a mobile phone (e.g., a smartphone), a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 24, the system 300 may include a host 308 and a memory system 302 having one or more memory devices 304 and a memory controller 306. The host 308 may be a processor of an electronic device, such as a central processing unit (CPU), or a system-on-chip (SoC), such as an application processor (AP). The host 308 may be configured to send or receive data to or from the memory devices 304.

The memory controller 306 is coupled to the memory devices 304 and host 308 and is configured to control the memory devices 304, according to some implementations. The memory controller 306 may manage the data stored in the memory devices 304 and communicate with the host 308. In some embodiments, the memory controller 306 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some other embodiments, the memory controller 306 is designed for operating in a high duty-cycle environment, such as SSDs or embedded multi-media-cards (eMMCs) used as data storage for mobile devices, such as smartphones, tablets, laptop computers, etc., and enterprise storage arrays. The memory controller 306 may be configured to control operations of the memory device 304, such as read, erase, and program operations.

The memory controller 306 may also be configured to manage various functions with respect to the data stored or to be stored in the memory device 304 including, but not limited to bad-block management, garbage collection, logical-to-physical address conversion, wear leveling, etc. In some implementations, the memory controller 306 is further configured to process error correction codes (ECCs) with respect to the data read from or written to the memory device 304. Any other suitable functions may be performed by the memory controller 306 as well, for example, formatting the memory device 304. The memory controller 306 may communicate with an external device (e.g., the host 308) according to a particular communication protocol. For example, the memory controller 306 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

The memory device 304 may be any memory device disclosed in the present disclosure, such as the 3D memory device 180 shown in FIG. 22. As the 3D memory device 180 may have a high-capacity DRAM providing a high-capacity mapping cache due to the reasons described above, when the device 180 is used, the performance of the system 300 may be improved at a reduced cost.

The memory controller 306 and one or more memory devices 304 may be integrated into various types of storage devices, for example, be included in the same package, such as a universal Flash storage (UFS) package or an eMMC package. That is, the memory system 302 may be implemented and packaged into different types of end electronic products. FIGS. 25 and 26 exemplarily illustrate block diagrams of a memory card 400 and an SSD 500 according to various aspects of the present disclosure. As shown in FIG. 25, a memory controller 404 and a single memory device 402 may be integrated into the memory card 400. The memory device 402 may be any memory device illustrated above, such as the 3D memory device 180 shown in FIG. 22. The memory card 400 may include a PC card (personal computer memory card international association (PCMCIA)), a CF card, a smart media (SM) card, a memory stick, a multimedia card (MMC, RS-MMC, or MMCmicro), an SD card (SD, miniSD, microSD, or SDHC), a UFS, etc. The memory card 400 may further include a memory card connector 406 configured to couple the memory card 400 to a host (e.g., the host 308 shown in FIG. 24). As shown in FIG. 26, a memory controller 504 and multiple memory devices 502 may be integrated into the SSD 500. The memory devices 502 may be any aforementioned memory device, such as the 3D memory device 180 shown in FIG. 22. The SSD 500 may further include an SSD connector 506 configured to couple the SSD 500 to a host (e.g., the host 308 shown in FIG. 24). In some embodiments, the storage capacity and/or the operation speed of the SSD 500 is greater than those of the memory card 400.

Although the principles and implementations of the present disclosure are described by using specific aspects in the specification, the foregoing descriptions of the aspects are only intended to help understand the present disclosure. In addition, features of aforementioned different aspects may be combined to form additional aspects. A person of ordinary skill in the art may make modifications to the specific implementations and application range according to the idea of the present disclosure. Hence, the content of the specification should not be construed as a limitation to the present disclosure.

What is claimed is:

1. A three-dimensional (3D) memory device, comprising:
a first die of a 3D memory structure; and
a second die bonded with the first die, wherein the second die comprises a plurality of dynamic random-access memory (DRAM) cells, and the 3D memory structure comprises a conductor/insulator stack including a conductive layer and a dielectric layer alternatingly stacked, and a region of memory cells in the conductor/insulator stack.

2. The 3D memory device according to claim 1, further comprising:
a third die of a periphery structure bonded with the first die and/or the second die.

3. The 3D memory device according to claim 1, wherein the 3D memory structure further includes a periphery structure.

4. The 3D memory device according to claim 1, wherein the plurality of DRAM cells form a pattern in a plane and each DRAM cell includes a gate structure extending in a direction perpendicular to the plane.

5. The 3D memory device according to claim 4, wherein the plurality of DRAM cells include a capacitor with an electrode extending in the direction.

6. The 3D memory device according to claim 1, wherein the second die further comprises:
a circuit arranged to support operation of the 3D memory device.

7. The 3D memory device according to claim 6, wherein the circuit includes a complementary metal-oxide semiconductor (CMOS) circuit that has a low supply voltage below 30 volts.

8. The 3D memory device according to claim 7, wherein the third die includes a first circuit with a first supply voltage and a second circuit with a second supply voltage, the first supply voltage is larger than the second supply voltage, and the second supply voltage is larger than the low supply voltage.

9. The 3D memory device according to claim 1, wherein the second die includes a substrate and a dielectric region that penetrates the substrate along a direction perpendicular to the substrate.

10. A memory device, comprising:
a first die of a memory structure comprising a plurality of memory cells;
a second die comprising a plurality of dynamic random-access memory (DRAM) cells; and
a third die of a periphery structure comprising a periphery circuit, wherein the first, second, and third dies are stacked.

11. The memory device according to claim 10, wherein the memory structure further comprises a conductor/insulator stack including a conductive layer and a dielectric layer alternatingly stacked, and the plurality of memory cells are arranged in the conductor/insulator stack.

12. The memory device according to claim 10, wherein the first, second, and third dies are bonded together.

13. The memory device according to claim 10, wherein the second die is between the first die and the third die.

14. The memory device according to claim 10, wherein the plurality of DRAM cells form a pattern in a plane and each DRAM cell include a gate structure extending in a direction perpendicular to the plane.

15. The memory device according to claim 14, wherein the plurality of DRAM cells include a capacitor with an electrode extending in the direction.

16. A method for fabricating a three-dimensional (3D) memory device, comprising:
providing a first die of a 3D memory structure, the 3D memory structure comprising a conductor/insulator stack including a conductive layer and a dielectric layer alternatingly stacked, and a region of memory cells in the conductor/insulator stack;
providing a second die, the second die comprising a plurality of dynamic random-access memory (DRAM) cells; and
bonding the first die with the second die.

17. The method according to claim 16, further comprising:
bonding a third die of a periphery structure with the first die and/or the second die.

18. The method according to claim 16, wherein the second die further comprises:
a complementary metal-oxide semiconductor (CMOS) circuit.

19. The method according to claim 18, further comprising:
fabricating the plurality of DRAM cells using a first process; and
fabricating the CMOS circuit using a second process, the first and second processes being a same process or similar processes.

20. The method according to claim 18, further comprising:
before bonding the first die with the second die, thinning a substrate of the second die to expose a dielectric region and cause the dielectric region to penetrate through the substrate along a direction perpendicular to the substrate.
